(19) United States
(12) Patent Application Publication
(10) Pub. No.: US 2026/0305089 A1
(43) Pub. Date: Oct. 1, 2026

(54) DISPLAY DEVICE

(71) Applicant: Samsung Display Co., LTD., Yongin-si (KR)

(72) Inventors: Eun Byul KIM, Yongin-si (KR); Han Bum KWON, Yongin-si (KR); Young Min AHN, Yongin-si (KR); Kyung Bin CHOI, Yongin-si (KR)

(21) Appl. No.: 19/429,114

(22) Filed: Dec. 22, 2025

(30) Foreign Application Priority Data
Mar. 28, 2025 (KR) 10-2025-0040264

(51) Int. Cl. H10K 59/131; H10K 59/124; H10K 59/127; H10K 59/88; H10K 102/00

(52) U.S. Cl. CPC H10K 59/131; H10K 59/124; H10K 59/1275; H10K 59/88; H10K 2102/351

(57) ABSTRACT

A display device includes a first substrate; a display panel including a first signal pad, a via layer, and a second signal pad; and a driver circuit connected to the first signal pad and the second signal pad. The driver circuit includes: a second substrate, a first circuit signal pad , a circuit fixing pad, and a second circuit signal pad. The via layer of the display panel includes a via hole penetrating the via layer. The the first circuit signal pad and the second circuit signal pad of the driver circuit are connected with the first signal pad and the second signal pad of the display panel, respectively. The circuit fixing pad overlaps with the via hole of the display panel and is further located inside the via hole.

This application claims priority to Korean Patent Application No. 10-2025-0040264, filed on Mar. 28, 2025, and all the benefits accruing therefrom under 35 U.S.C. §119, the content of which in its entirety is herein incorporated by reference.

### BACKGROUND

### 1. Field

The present disclosure relates to a display device.

### 2. Description of the Related Art

Multimedia electronic devices such as, for example, televisions, mobile phones, tablet PCs, navigation systems, and game consoles may include a display module that displays images and detects external inputs. Such a display module may be bonded to and in turn electrically connected to a driver chip that provides electrical signals for displaying images.

### SUMMARY

Aspects of the present disclosure provide a display device that can prevent slipping that causes misalignment during a process of bonding between a display panel and a driver circuit.

It should be noted that objects of the present disclosure are not limited to the above-mentioned object; and other objects of the present disclosure will be apparent to those skilled in the art from the following descriptions.

According to an aspect of the present disclosure, a display device includes a first substrate; a display panel including a first signal pad located on the first substrate, a via layer located on an outer side of the first signal pad, and a second signal pad located on an outer side of the via layer; and a driver circuit located on the display panel and connected to the first signal pad and the second signal pad of the display panel, wherein the driver circuit includes: a second substrate, and a first circuit signal pad located on the second substrate, a circuit fixing pad located on an outer side of the first circuit signal pad, and a second circuit signal pad located on an outer side of the circuit fixing pad, wherein the via layer of the display panel includes a via hole penetrating the via layer, wherein the first circuit signal pad and the second circuit signal pad of the driver circuit are connected with the first signal pad and the second signal pad of the display panel, respectively, and wherein the circuit fixing pad overlaps with the via hole of the display panel and is further located inside the via hole.

In an embodiment, the display panel further includes an insulating layer located between the first substrate and the via layer, wherein the driver circuit further includes a circuit fixing insulating layer covering the circuit fixing pad, and wherein a surface of the circuit fixing insulating layer facing the display panel is in direct contact with the insulating layer of the display panel.

In an embodiment, a surface of the circuit fixing insulating layer that crosses the surface facing the display panel is not in direct contact with an inner surface of the via layer defining the via hole.

In an embodiment, a surface of the circuit fixing insulating layer that crosses the surface facing the display panel is in direct contact with an inner surface of the via layer defining the via hole.

In an embodiment, the display panel further includes an insulating layer located between the first substrate and the via layer, wherein the driver circuit further includes a circuit fixing insulating layer covering the circuit fixing pad, and wherein a surface of the circuit fixing insulating layer facing the display panel is not in direct contact with the insulating layer of the display panel.

In an embodiment, a surface of the circuit fixing insulating layer that crosses the surface facing the display panel is not in direct contact with an inner surface of the via layer defining the via hole.

In an embodiment, a surface of the circuit fixing insulating layer that crosses the surface facing the display panel is in direct contact with an inner surface of the via layer defining the via hole.

In an embodiment, the driver circuit further includes a circuit dummy pad located between the first circuit signal pad and the second circuit signal pad and located around the circuit fixing pad, and wherein a thickness of the circuit dummy pad and a thickness of the circuit fixing pad are different from each other.

In an embodiment, the thickness of the circuit fixing pad is greater than the thickness of the circuit dummy pad.

In an embodiment, the driver circuit further includes a circuit dummy insulating layer covering the circuit dummy pad, and wherein a surface of the circuit dummy insulating layer facing the display panel is in direct contact with the via layer.

In an embodiment, the driver circuit further includes a circuit dummy insulating layer covering the circuit dummy pad, and wherein a surface of the circuit dummy insulating layer facing the display panel is not in direct contact with the via layer.

In an embodiment, the via layer includes a first via layer located on the first substrate and a second via layer located on the first via layer, and wherein the via hole penetrates the second via layer but not the first via layer.

In an embodiment, the driver circuit further includes a circuit fixing insulating layer covering the circuit fixing pad, and wherein a surface of the circuit fixing insulating layer facing the display panel is in direct contact with the first via layer.

In an embodiment, the driver circuit further includes a circuit fixing insulating layer covering the circuit fixing pad, and wherein a surface of the circuit fixing insulating layer facing the display panel is not in direct contact with the first via layer.

According to an aspect of the present disclosure, a display device includes a first substrate; a display panel including a first signal pad located on the first substrate, a via layer located on an outer side of the first signal pad, and a second signal pad located on an outer side of the via layer; and a driver circuit located on the display panel and connected to the first signal pad and the second signal pad of the display panel, wherein the driver circuit includes: a second substrate, and a first circuit signal pad located on the second substrate, a plurality of circuit dummy pads located on an outer side of the first circuit signal pad and spaced apart from one another, and a second circuit signal pad located on an outer side of each of the plurality of circuit dummy pads, wherein the first circuit signal pad and the second circuit signal pad of the driver circuit are connected to the first signal pad and the second signal pad of the display panel, respectively, wherein the via layer of the display panel further includes a via protruding pattern protruding toward the driver circuit, and wherein the via protruding pattern is located between the plurality of circuit dummy pads of the driver circuit.

In an embodiment, a surface of the via protruding pattern facing the driver circuit is in direct contact with the second substrate of the driver circuit.

In an embodiment, a surface of the via protruding pattern facing the driver circuit is not in direct contact with the second substrate of the driver circuit.

In an embodiment, the driver circuit further includes a circuit dummy insulating layer covering the plurality of circuit dummy pads, and wherein a surface of the circuit dummy insulating layer facing the display panel is in direct contact with the via layer.

In an embodiment, the driver circuit further includes a circuit dummy insulating layer covering the plurality of circuit dummy pads, and wherein a surface of the circuit dummy insulating layer facing the display panel is not in direct contact with the via layer.

According to an aspect of the present disclosure, an electronic device includes a display device for displaying an image; and a processor for transmitting an image data signal for displaying the image to the display device, wherein the display device includes: a first substrate; a display panel including a first signal pad located on the first substrate, a via layer located on an outer side of the first signal pad, and a second signal pad located on an outer side of the via layer; and a driver circuit located on the display panel and connected to the first signal pad and the second signal pad of the display panel, wherein the driver circuit includes: a second substrate, and a first circuit signal pad located on the second substrate, a circuit fixing pad located on an outer side of the first circuit signal pad, and a second circuit signal pad located on an outer side of the circuit fixing pad, wherein the via layer of the display panel includes a via hole penetrating the via layer, wherein the first circuit signal pad and the second circuit signal pad of the driver circuit are connected with the first signal pad and the second signal pad of the display panel, respectively, and wherein the circuit fixing pad overlaps with the via hole of the display panel and is further located inside the via hole.

The details of one or more embodiments of the subject matter described in this specification are set forth in the accompanying drawings and the description below.

According to embodiments of the present disclosure, it is possible to prevent slipping that causes misalignment between a display panel and a driver circuit in a display device during a process of bonding between the display panel and the driver circuit, thereby providing the display device with improved reliability.

It should be noted that effects of the present disclosure are not limited to those described herein and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to an embodiment of the present disclosure.

FIG. 2 is a plan view of the display device of FIG. 1 from which a driver circuit and a flexible printed circuit board has been removed.

FIG. 3 is an enlarged view of portion B1 of FIG. 2.

FIG. 4 is a cross-sectional view taken along line X1 - X1' of FIG. 3.

FIG. 5 is a cross-sectional view of a display device according to an embodiment of the present disclosure when a display panel and a driver circuit are bonded together, taken along line X1 – X1' of FIG. 3.

FIG. 6 is an enlarged view of portion B3 of the display device according to the embodiment of the present disclosure when the display panel and the driver circuit are bonded together.

FIGS. 7 and 8 are cross-sectional views of a display device according to another embodiment of the present disclosure, taken along line X1 – X1' of FIG. 3.

FIGS. 9 to 11 are enlarged views of portion B1 of FIG. 3 in a display device according to another embodiment.

FIG. 12 is a cross-sectional view taken along line X3 – X3' of FIG. 11.

FIG. 13 is a block diagram of an electronic device according to an embodiment of the present disclosure.

FIG. 14 is a view illustrating electronic devices according to a variety of embodiments of the present disclosure.

### DETAILED DESCRIPTION

Embodiments supported by the present disclosure will now be described more fully hereinafter with reference to the accompanying drawings, in which example embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will filly convey the scope of example aspects of the present disclosure to those skilled in the art.

It will also be understood that when a layer is referred to as being "on" another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the present invention. Similarly, the second element could also be termed the first element.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Descriptions herein of adjacent elements of the same type (e.g., adjacent first signal pads PD1, adjacent protruding patterns PT) may refer to elements of the same type which follow one another in order in a direction, without a further element of the same type in between.

The term “adjacent” used herein with respect to two different elements (e.g., a via hole VH located adjacent to a corner of a via layer VIA) may refer to cases in which the two different elements are relatively close to but spaced apart from one another. In some aspects, elements described as adjacent to one another may be neighboring one another but spaced apart by a predetermined distance. For example, two elements described as adjacent to one another may be neighboring one another without other elements being located between the two elements.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described in detail with reference to the accompanying drawings.

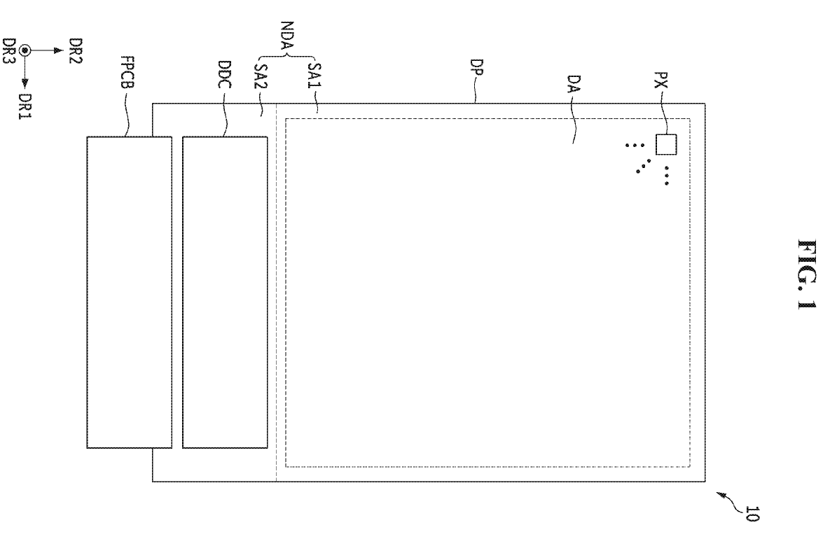

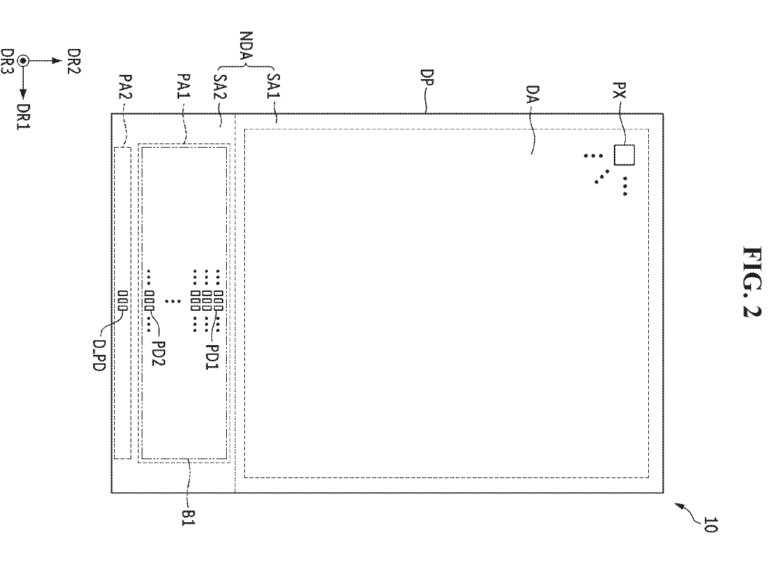

FIG. 1 is a plan view of a display device according to an embodiment of the present disclosure. FIG. 2 is a plan view of the display device of FIG. 1 from which a driver circuit and a flexible printed circuit board has been removed.

Referring to FIGS. 1 and 2, a display device 10 displays moving images or still images and may be used as a display screen of a variety of electronic devices.

The display device 10 may be a light-emitting display device such as, for example, an organic light-emitting display device including organic light-emitting diodes, a quantum-dot light-emitting display device including quantum-dot light-emitting layer, and an ultra-small light-emitting display device including ultra-small light-emitting diodes such as, for example, micro or nano light-emitting diodes (micro LEDs or nano LEDs). It should be understood, however, that embodiments of the present disclosure are not limited thereto. For example, the display device 10 may be other types of display devices than light-emitting display devices. In the following descriptions, a light-emitting display device (e.g., an organic light-emitting display device) is disclosed as the display device 10.

The shape of the display device 10 may be modified in a variety of ways. For example, the display device 10 may have shapes such as a rectangle with longer vertical sides, a rectangle with longer horizontal sides, a square, a quadrangle with rounded corners (vertices), other polygons, a circle, or the like. In the example illustrated in FIGS. 1 and 2, the display device 10 has a rectangular shape with the longer sides in a second direction DR2.

As used herein, a first direction DR1 may be parallel to the shorter sides of the display device 10, for example, the horizontal direction of the display device 10. A second direction DR2 may be parallel to the longer sides of the display device 10, for example, the vertical direction of the display device 10. A third direction DR3 may refer to the thickness direction of the display device 10.

The display device 10 may include a display panel DP and a driver circuit DDC. In some aspects, the display device 10 may further include a flexible printed circuit board FPCB.

The display panel DP may be a rigid display panel that is not substantially deformed, or a flexible display panel that can be deformed, i.e., at least partially folded, bent or rolled. The display panel DP may be provided to the display device 10 without being bent or with being partially bent.

The display panel DP may include a display area DA and a non-display area NDA. A plurality of pixels PX may be arranged in the display area DA. The pixels PX can display images. Each of the pixels PX may include a pixel driver circuit including transistors (e.g., a switching transistor, a driving transistor, or the like) and at least one capacitor, and a light-emitting element electrically connected to the pixel driver circuit. The pixels PX may generate light in response to an electrical signal applied to each of the pixels PX and may display images through the display area DA. According to an embodiment, some of the pixels PX may include, but is not limited to, transistors arranged in the non-display area NDA. The display area DA may have a variety of shapes depending on embodiments. For example, the display area DA may have a rectangular shape, a non-rectangular polygonal shape, a circular shape, an elliptical shape, an irregular shape, or other shapes. According to an embodiment of the present disclosure, the display area DA may have a shape that conforms to the shape of the display panel DP.

The non-display area NDA may be located around the display area DA. The non-display area NDA may include a first peripheral area SA1 surrounding the display area DA and a second peripheral area SA2 protruding downward from the first peripheral area SA1.

The second peripheral area SA2 may include a first pad area PA1 on which the driver circuit DDC is arranged, and a second pad area PA2 on which the flexible printed circuit board FPCB is arranged. The first pad area PA1 and the second pad area PA2 may be spaced apart from each other.

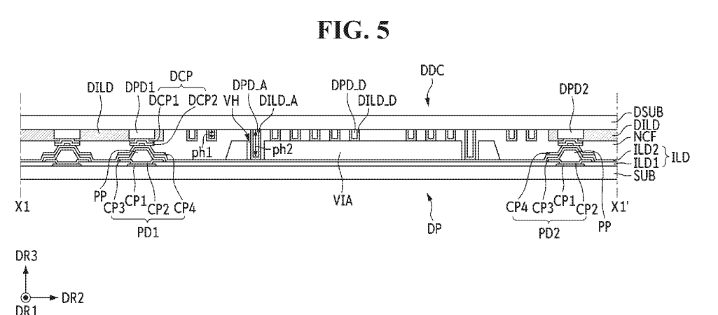

The first pad area PA1 may be located on the second peripheral area SA2 and may be located closely to and spaced apart from the display area DA. The driver circuit DDC described herein may be connected to the first pad area PA1. The driver circuit DDC may be implemented as a driver chip. In the first pad area PA1, a plurality of first pads PD1 and second pads PD2 connected to the driver circuit DDC may be arranged. The first signal pads PD1 may be associated with output pads of the driver circuit DDC of FIG. 5, which will be described later, and may be input pads that receive signals from the driver circuit DDC. The second signal pads PD2 may be associated with input pads of the driver circuit DDC of FIG. 5, which will be described later, and may be output pads that output signals of the driver circuit DDC.

The second pad area PA2 may be located on the second peripheral area SA2 and may be more distant from the display area DA than the first pad area PA1. A flexible printed circuit film FPCB including a timing controller and a supply voltage generator may be connected to the second pad area PA2. Display pads D_PD connected to the flexible printed circuit board FPCB may be arranged in the second pad area PA2. The display pads D_PD may be panel input pads that receive signals from the flexible printed circuit board FPCB.

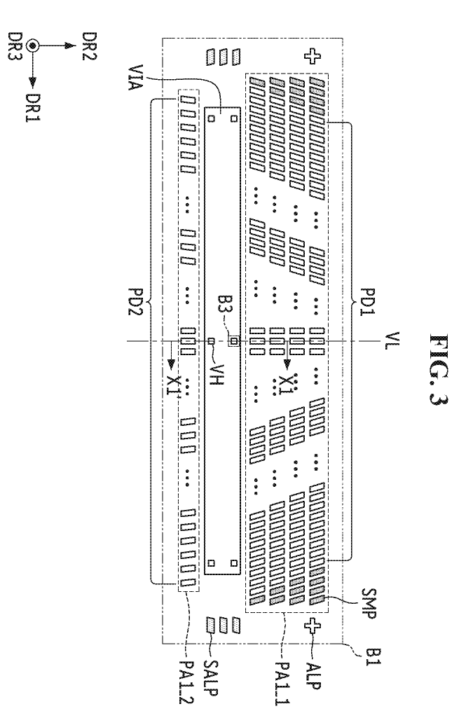

FIG. 3 is an enlarged view of portion B1 of FIG. 2. FIG. 3 is a plan view of a part of the display panel DP that corresponds to the first pad area PA1 of the second peripheral area SA2.

Referring to FIG. 3, the first pad area PA1 may include a first subsidiary pad area PA1_1, a second subsidiary pad area PA1_2, and a via layer VIA.

The first subsidiary pad area PA1_1 may be defined as an area where the first signal pads PD1 are arranged. The second subsidiary pad area PA1_2 may be defined as an area where the second signal pads PD1 are arranged.

The first signal pads PD1 may be arranged in the first direction DR1 and the second direction DR2 in the first subsidiary pad area PA1_1. Among the first signal pads PD1, first signal pads PD1 arranged along the first direction DR1 may be defined as input pad rows. In the example illustrated in FIG. 3, four input pad rows are arranged in the second direction DR2. The arrangement of the first signal pads PD1 is not particularly limited as long as at least two input pad rows are arranged in the second direction DR2.

The second signal pads PD2 may be arranged in the first direction DR1 in the second subsidiary pad area PA1_2. The second signal pads PD2 may be arranged in a single pad row, and the single pad row may be defined as an output pad row. It should be understood, however, that the arrangement of the second signal pads PD2 is not limited thereto.

Among the first signal pads PD1, the first center pads PD1 arranged at the center in the first direction DR1 may be located on a reference line VL. The first center pads PD1 may extend in the second direction DR2. Among the first signal pads PD1, the first signal pads PD1 arranged on the left and right sides of the reference line VL may extend with inclinations with respect to the reference line VL. The first signal pads PD1 arranged on the left side of the reference line VL may extend to form an acute angle in the clockwise direction with respect to the reference line VL. The first signal pads PD1 arranged on the right side of the reference line VL may extend to form an acute angle in the counterclockwise direction with respect to the reference line VL.

Among the second signal pads PD2, the second center pads PD1 arranged at the center in the first direction DR1 may be located on the reference line VL. The second center pads may extend in the second direction DR2. Among the second signal pads PD2, the second signal pads PD2 arranged on the left and right sides of the reference line VL may extend with inclinations with respect to the reference line VL. Some of the second signal pads PD2 arranged on the left side of the reference line VL may extend to form an acute angle in the clockwise direction with respect to the reference line VL, and some of the second signal pads PD2 arranged on the right side may extend to form an acute angle in the counterclockwise direction with respect to the reference line VL.

The via layer VIA may be located between the first subsidiary pad area PA1_1 and the second subsidiary pad area PA1_2. The via layer VIA may include a via hole VH penetrating the via layer VIA. There may be a plurality of via holes VH located in the first direction DR1 and the second direction DR2 in the via layer VIA. For example, some of the via holes VH may be located on the same reference line VL as the first and second center pads PD1 and PD2 that are located at the center of the first and second signal pads PD1 and PD2 in the first direction DR1 and may be arranged in the second direction DR2. Some others of the via holes VH may be located adjacent to the left and right corners of the via layer VIA along the first direction DR1 from the via holes VH located on the reference line VL. Among the via holes VH, the via holes VH arranged in the first direction DR1 may be defined as a row of via holes VH. Although two rows of via holes VH are arranged in the second direction DR2 in the example illustrated in FIG. 3, the arrangement of the via holes VH in the via layer VIA is not limited thereto. A circuit fixing pad DPD_A of the driver circuit DDC of FIG. 5, which will be described later, may be located inside the via hole VIA. As the circuit fixing pads DPD_A of the driver circuit DDC are inserted into the via holes VH of the via layer VIA of the display panel DP, it is possible to prevent slipping that causes misalignment between the pads of the display panel DP and the pads of the driver circuit DDC when the display panel DP and the driver circuit DDC are bonded together. As a result, the reliability of the display device 10 can be improved. Although the via hole VH has a rectangular shape in the plan view of FIG. 3 as an example, the shape of the via hole VH is not particularly limited as long as the circuit fixing pad DPD_A of the driver circuit DDC can be inserted in it. The via hole VH may have a circular or polygonal shape.

The display panel DP may further include dummy pads SMP. The dummy pads SMP may be arranged in the first pad area PA1. Each of the dummy pads SMP may be an electrically isolated pad and may be arranged to make up for the area between the edges of the second peripheral area SA2 and the first signal pads PD1. The dummy pads SMP may be arranged on the outer sides of the first signal pads PD1 arranged at the outermost positions in at least one of the first to fourth input pad rows. The dummy pads SMP may be arranged adjacent to the left and right sides of the first pad area PA1. Although the dummy pads SMP are arranged on the outer sides of the first to fourth input pad rows in the example illustrated in FIG. 3, the arrangement of the dummy pads SMP is not limited thereto. The dummy pads SMP may extend in a direction parallel to the direction in which the adjacent first signal pads PD1 extend. Some of the dummy pads SMP arranged adjacent to a pad row may be arranged in parallel with the first signal pads PD1 of that pad row in the first direction DR1.

The display panel DP may further include an alignment pad ALP. The alignment pad ALP may be arranged in the first pad area PA1. There may be a plurality of alignment pads ALP. The alignment pads ALP may be located adjacent to the left and right corners of the first pad area PA1, respectively. The alignment pads ALP may be identification marks or alignment marks for aligning the driver circuit DDC with the first pad area PA1 of the display panel DP in a process of bonding the driver circuit DDC on the first pad area PA1 of the display panel DP. Although the alignment pads ALP have a cross shape in the example illustrated in FIG. 3, the shape of the alignment pads ALP is not particularly limited and may have a circular or polygonal shape as long as they can be used to align the driver circuit DDC with the display panel DP.

According to an embodiment of the present disclosure, the dummy pads SMP and the alignment pads ALP may be formed via the same process, and the dummy pads SMP and the alignment pads ALP may include the same material. According to an embodiment of the present disclosure, at least one of the dummy pads SMP and the alignment pads ALP may include the same material as the first signal pads PD1. At least one of the dummy pads SMP and the alignment pads ALP may be formed via the same process as the first signal pads PD1.

The display panel DP may further include a subsidiary alignment pad SALP. The subsidiary alignment pad SALP may be located in the first pad area PA1. There may be a plurality of subsidiary alignment pads SALP. Some of the subsidiary alignment pads SALP may be arranged adjacent to the left side of the via layer VIA, and some others of them may be arranged adjacent to the right side of the via layer VIA. The subsidiary alignment pads SALP may be identification marks or alignment marks for aligning the driver circuit DDC with the display panel DP or for inspecting whether the driver circuit DDC and the display panel DP are properly aligned in a process of bonding the driver circuit DDC on the first pad area PA1 of the display panel DP. Although the subsidiary alignment pads SALP have a quadrangular shape in the example illustrated in FIG. 3, the shape of the subsidiary alignment pads SALP is not particularly limited and may have a circular or polygonal shape as long as they can be used to check if the driver circuit DDC and the display panel DP are properly aligned.

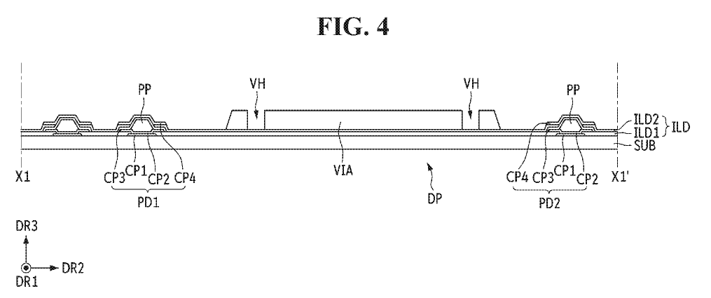

FIG. 4 is a cross-sectional view taken along line X1 - X1' of FIG. 3. FIG. 4 illustrates an example of the cross section of the first signal pads PD1, the via layer VIA, and the second signal pads PD2 arranged in the first pad area PA1.

Referring to FIG. 4, the display panel DP may include a substrate SUB, a first pad PD1, a second pad PD2, a first interlayer dielectric layer ILD1, a second interlayer dielectric layer ILD2, and a via layer VIA.

The substrate SUB may be a base member that supports layers of the display panel DP. According to some embodiments, the substrate SUB may be a rigid substrate and may include a glass material or a metal material. Alternatively, in some embodiments, the substrate SUB may be a flexible substrate that can be bent, folded, rolled and so on, and may include, but is not limited to, a polymer resin such as polyimide (PI).

The first and second signal pads PD1 and PD2 may be located on the substrate SUB. Each of the first and second signal pads PD1 and PD2 may include a plurality of conductive patterns CP1, CP2, CP3 and CP4 arranged in the thickness direction.

The first conductive patterns CP1 of the first and second signal pads PD1 and PD2 may be located on the substrate SUB1. The first conductive patterns CP1 may be formed via the same process as the gate electrode of the transistor. For example, the first conductive patterns CP1 of the first and second signal pads PD1 and PD2 and the gate electrode may be formed by forming a conductive layer on the substrate SUB via a deposition process such as sputtering and chemical vapor deposition, and then patterning the conductive layer. The first conductive patterns CP1 of the first and second signal pads PD1 and PD2 may be arranged on the same layer as the gate electrode of the transistor and may include the same material.

The first interlayer dielectric layer ILD1 may be located over the substrate SUB and the first conductive patterns CP1. The first interlayer dielectric layer ILD1 may include through holes exposing the upper surfaces of the first conductive pads CP1. The first interlayer dielectric layer ILD1 may be formed by depositing a deposition material over the substrate SUB and the first conductive patterns CP1 and then etching the deposition material such that the upper surfaces of the first conductive patterns CP1 of the first and second signal pads PD1 and PD2 are partially exposed.

The second conductive patterns CP2 of the first and second signal pads PD1 and PD2 may be located on the exposed first conductive patterns CP1, respectively, and may overlap with the first conductive patterns CP1. The second conductive patterns CP2 may be in contact with the first conductive patterns CP1, respectively. Parts of the second conductive patterns CP2 may further be located on the first interlayer dielectric layer ILD1. The second conductive patterns CP2 may be formed via the same process as first source/drain electrodes of the transistor (not illustrated). For example, a conductive layer may be formed on the first interlayer dielectric layer ILD1 via a deposition process such as sputtering and chemical vapor deposition, and then the conductive layer may be patterned, to form second conductive patterns CP2 of the first and second signal pads PD1 and PD2 and the first source/drain electrodes. The second conductive patterns CP2 of the first and second signal pads PD1 and PD2 may be arranged on the same layer as the first source/drain electrodes of the transistor and may include the same material.

Protruding patterns PP may be located on the second conductive patterns CP2. For example, the protruding patterns PP may be located on the second conductive patterns CP2 and may overlap with the through holes exposing the upper surfaces of the first conductive pads CP1. The protruding patterns PP may be in contact with the second conductive patterns CP2, respectively. The protruding patterns PP may have a quadrangular shape. For example, the protruding patterns PP may have a quadrangular shape when viewed from the top. It should be understood, however, that the embodiments of the present disclosure are not limited thereto. The protruding patterns PP may have a variety of shapes such as, for example, a circle and a triangle. In the cross-sectional view as illustrated in FIG. 4, the protruding patterns PP may have a quadrangular shape in which the width of the upper surface is smaller than the width of the lower surface. For example, in a cross-sectional view, the protruding patterns PP may have a trapezoidal shape that is convex toward the driver circuit DDC. It should be understood, however, that the embodiments of the present disclosure are not limited thereto. In a cross-sectional view, the protruding patterns PP may have a variety of shapes such as, for example, a hemisphere and a triangle. The protruding patterns PP may include a polymer-based material. The polymer-based material may include an acrylic resin, an epoxy resin, polyimide, polyethylene, or the like. According to some embodiments, the protruding patterns PP may be an inelastic polymer material. Alternatively, in some embodiments, the protruding patterns PP may be an elastic polymer material.

The third conductive patterns CP3 of the first and second signal pads PD1 and PD2 may be located on the protruding patterns PP and the second conductive patterns CP2 and may overlap with the protruding patterns PP and the second conductive patterns CP2, respectively. The third conductive patterns CP3 may be in contact with the second conductive patterns CP2 and the protruding patterns PP, respectively. Parts of the third conductive patterns CP3 may further be located on the first interlayer dielectric layer ILD1. The third conductive patterns CP3 may be formed via the same process as second source/drain electrodes of the transistor (not illustrated). For example, the third conductive patterns CP3 of the first and second signal pads PD1 and PD2 and the second source/drain electrodes may be formed by forming a conductive layer via a deposition process such as sputtering and chemical vapor deposition, and then patterning the conductive layer. The third conductive patterns CP3 of the first and second signal pads PD1 and PD2 may be arranged on the same layer as the second source/drain electrodes of the transistor and may include the same material.

The second interlayer dielectric layer ILD2 may be located over the third conductive patterns CP3 and the first interlayer dielectric layer ILD1. The second interlayer dielectric layer ILD2 may include through holes exposing the upper surfaces of the third conductive pads CP3. The second interlayer dielectric layer ILD2 may be formed by depositing a deposition material over the first interlayer dielectric layer ILD1 the third conductive patterns CP3 and then etching the deposition material such that the upper surfaces of the third conductive patterns CP3 of the first and second signal pads PD1 and PD2 are partially exposed.

The fourth conductive patterns CP4 of the first and second signal pads PD1 and PD2 may be located on the third conductive patterns CP3 exposed from the second interlayer dielectric layer ILD2, and may overlap with the third conductive patterns CP3, respectively. The fourth conductive patterns CP4 may be in contact with the third conductive patterns CP3. Parts of the fourth conductive patterns CP4 may further be located on the second interlayer dielectric layer ILD2. The fourth conductive patterns CP4 of the first and second signal pads PD1 and PD2 may be formed via the same process as one of the conductive layers of a touch sensing unit (not illustrated). For example, a conductive layer of the touch sensing unit and the fourth conductive patterns CP4 of the first and second signal pads PD1 and PD2 may be formed by forming the second interlayer dielectric layer ILD2 on the first interlayer dielectric layer ILD1 and the third conductive patterns CP3, and then forming a conductive layer on the second interlayer dielectric layer ILD2 via a deposition process such as sputtering and chemical vapor deposition to pattern the conductive layer. The fourth conductive patterns CP4 may be arranged on the same layer as the conductive layer of the touch sensing unit and may include the same material.

The third conductive patterns CP3 and the fourth conductive patterns CP4 on the protruding patterns PP may have depressions and elevations. For example, the first and second signal pads PD1 and PD2 may have elevations protruding in the third direction DR3 and depressions recessed in the opposite direction of the third direction DR3 (hereinafter, the third opposite direction). Specifically, the third conductive patterns CP3 and the fourth conductive patterns CP4 may protrude in the third direction DR3 on the protruding patterns PT and may be recessed in the third opposite direction between adjacent protruding patterns PT. The fourth conductive patterns CP4 protruding in the third direction DR3 may come into contact with the circuit conductive patterns DCP of the driver circuit DDC of FIG. 5, which will be described later. By such contact, the first and second signal pads PD1 and PD2 of the display panel DP and the first and second circuit signal pads DPD1 and DPD2 of the driver circuit DDC of FIG. 5, which will be described later, may be electrically connected, respectively.

The via layer VIA may be located on the second interlayer dielectric layer ILD2. As illustrated in FIG. 3, when viewed from the top, the via layer VIA may be located between the first signal pads PD1 and the second signal pads PD2 in the second direction DR2. In the cross-sectional view as illustrated in FIG. 4, the via layer VIA may be located on the outer side of the first signal pads PD1, and the second signal pads PD2 may be located on the outer side of the via layer VIA.

In the cross-sectional view as illustrated in FIG. 4, the via holes VH of the via layer VIA may be formed along the second direction DR2, and parts of the second interlayer dielectric layer ILD2 may be exposed by the via holes VH penetrating the via layer VIA. Although two via holes VH adjacent to the first signal pad PD1 and the second signal pad PD2 in the second direction DR2, respectively, are illustrated in FIG. 4, this is illustrative. The number and arrangement of the via holes VH may vary and are not limited to a particular embodiment.

FIG. 5 is a cross-sectional view of a display device according to an embodiment of the present disclosure when a display panel and a driver circuit are bonded together, taken along line X1 – X1' of FIG. 3. FIG. 5 illustrates an example of the cross-section of the display device 10 in which the driver circuit DDC is bonded on the display panel DP illustrated in FIG. 4.

The following descriptions will focus on differences, and the redundant descriptions will be omitted.

Referring to FIG. 5, the driver circuit DDC may be located on the first pad area PA1 of the display panel DP. The display device 10 may further include a non-conductive film (NCF) arranged between the display panel DP and the driver circuit DDC.

The driver circuit DDC may include a substrate DSUB, first circuit signal pads DPD1, second circuit signal pads DPD2, circuit dummy pads DPD_D, a circuit fixing pad DPD_A, an insulating layer DILD, a circuit dummy insulating layer DILD_D, a circuit fixing insulating layer DILD_A, and a conductive pattern DCP.

The substrate DSUB may be a base member that supports the layers of the driver circuit DDC. According to some embodiments, the substrate DSUB may be a rigid substrate and may include a glass material or a metal material. Alternatively, in some embodiments, the substrate DSUB may be a flexible substrate that can be bent, folded, rolled and so on, and may include, but is not limited to, a polymer resin such as polyimide (PI).

First circuit signal pads DPD1, second circuit signal pads DPD2, circuit dummy pads DPD_D, and circuit fixing pads DPD_A may be located on the substrate DSUB.

The first circuit signal pads DPD1 may be associated with the first signal pads PD1 of the display panel DP and may be output pads that output signals to the first signal pads PD1. The second circuit signal pads DPD2 may be associated with the second signal pads PD2 of the display panel DP and may be input pads that receive signals of the second signal pads PD2.

The circuit dummy pads DPD_D may be located between the first circuit signal pads DPD1 and the second circuit signal pads DPD2 in the second direction DR2. The circuit dummy pads DPD_D may be arranged in the first direction DR1 and the second direction DR2. Among the circuit dummy pads DPD_D, the circuit dummy pads DPD_D arranged in the first direction DR1 may be defined as pad rows. The pad rows of the circuit dummy pads DPD_D may be arranged in the second direction DR2. Each of the circuit dummy pads DPD_D may be an electrically isolated pad and may be arranged to make up for the area between the first circuit signal pads DPD1 and the second circuit signal pads DPD2 in the second direction DR2.

Each of the circuit fixing pads DPD_A may be located between the circuit dummy pads DPD_D in the second direction DR2, may overlap with the via hole VH of the via layer VIA of the display panel DP in the third direction DR3, and may be located further inside the via hole VH. The circuit fixing pads DPD_A may be electrically isolated pads, and may be inserted into the via hole VH of the via layer VIA of the display panel DP such that they work as anchors to prevent slipping in the process of bonding the driver circuit DDC to the display panel DP. In the cross-sectional view, the thickness ph1 of the circuit dummy pads DPD_D may be different from the thickness ph2 of the circuit fixing pads DPD_A. In some embodiments, the thickness of the circuit fixing pads ph2 may be greater than the thickness of the circuit dummy pads ph1. The circuit fixing pads DPD_A may be inserted into the via holes VH of the via layer VIA of the display panel DP. As the circuit fixing pads DPD_A of the driver circuit DDC are inserted into the via holes VH of the via layer VIA of the display panel DP, the circuit fixing pads DPD_A as inserted may prevent slipping that causes misalignment between the pads of the display panel DP and the pads of the driver circuit DDC when the display panel DP and the driver circuit DDC are bonded together. As a result, the reliability of the display device 10 can be improved.

The first circuit signal pads DPD1, the second circuit signal pads DPD2, the circuit dummy pads DPD_D, and the circuit fixing pads DPD_A may be formed via the same process. For example, the first and second circuit signal pads DPD1 and DPD2, the circuit dummy pads DPD_D and the circuit fixing pads DPD_A may be formed by forming a conductive layer on the substrate DSUB via a deposition process such as sputtering and chemical vapor deposition, and then patterning the conductive layer. The first and second circuit signal pads DPD1 and DPD2, the circuit dummy pads DPD_D, and the circuit fixing pads DPD_A may be arranged on the same layer and may include the same material. The first circuit signal pads DPD1, the second circuit signal pads DPD2, the circuit dummy pads DPD_D, and the circuit fixing pads DPD_A may include aluminum (Al).

The insulating layer DILD may be located on the substrate SUB, the first circuit signal pads DPD1, and the second circuit signal pads DPD2. The insulating layer DILD may include through holes exposing the upper surfaces of the first and second circuit signal pads DPD1 and DPD2.

The driver circuit DDC may include a circuit dummy insulating layer DILD_D covering each of the circuit dummy pads DPD_D. A part of the circuit dummy insulating layer DILD_D may be further located on the substrate DSUB. In some embodiments, the surface of the circuit dummy insulating layer DILD_D which faces the display panel DP may be in direct contact with the via layer VIA of the display panel DP. Alternatively, in some embodiments, the surface of the circuit dummy insulating layer DILD_D which faces the display panel DP may not be in direct contact with the via layer VIA of the display panel DP.

The driver circuit DDC may include the circuit fixing insulating layer DILD_A covering each of the circuit fixing pads DPD_A. A part of the circuit fixing insulating layer DILD_A may be further located on the substrate DSUB. In the cross-sectional view as illustrated in FIG. 5, the circuit fixing insulating layer DILD_A may be located inside the via hole VIA of the via layer VIA of the display panel DP together with the circuit fixing pad DPD_A. In some embodiments, the surface of the circuit fixing insulating layer DILD_A which faces the display panel DP may be in direct contact with the second interlayer dielectric layer ILD2 of the display panel DP. Alternatively, in some embodiments, the surface of the circuit fixing insulating layer DILD_A which faces the display panel DP may not be in direct contact with the second interlayer dielectric layer ILD2 of the display panel DP.

The insulating layer DILD, the circuit dummy insulating layer DILD_D and the circuit fixing insulating layer DILD_A may be formed via the same process. For example, the insulating layer DILD, the circuit dummy insulating layer DILD_D and the circuit fixing insulating layer DILD_A may be formed by depositing a deposition material on the substrate DSUB, the first circuit signal pads DPD1, the second circuit signal pads DPD2, the circuit dummy pads DPD_D and the circuit fixing pads DPD_A, and then etching such that the upper surfaces of the first and second circuit signal pads DPD1 and DPD2 are partially exposed and the first and second circuit signal pads DPD1 and DPD2, the circuit dummy pads DPD_D and the circuit fixed pads DPD_A are covered and spaced apart from one another.

Conductive patterns DCP may be arranged on the insulating layer DILD. The conductive patterns DCP may have a multi-layer structure. For example, the conductive patterns DCP may include first conductive patterns DCP1 and second conductive patterns DCP2. The conductive patterns DCP may also be arranged inside the through holes of the insulating layer DILD that expose the upper surfaces of the first and second circuit signal pads DPD1 and DPD2, and accordingly may be in contact with the first and second circuit signal pads DPD1 and DPD2 exposed by the through holes, respectively. Accordingly, they may be electrically connected to the first and second circuit signal pads DPD1 and DPD2.

A non-conductive film NCF may be placed between the display panel DP and the driver circuit DDC. For example, the non-conductive film NCF may be placed between the first and second signal pads PD1 and PD2 and the first and second circuit signal pads DPD1 and DPD2. The display panel DP and the driver circuit DDC may be bonded together by the non-conductive film NCF. The non-conductive film NCF may be formed of a material including a thermosetting resin.

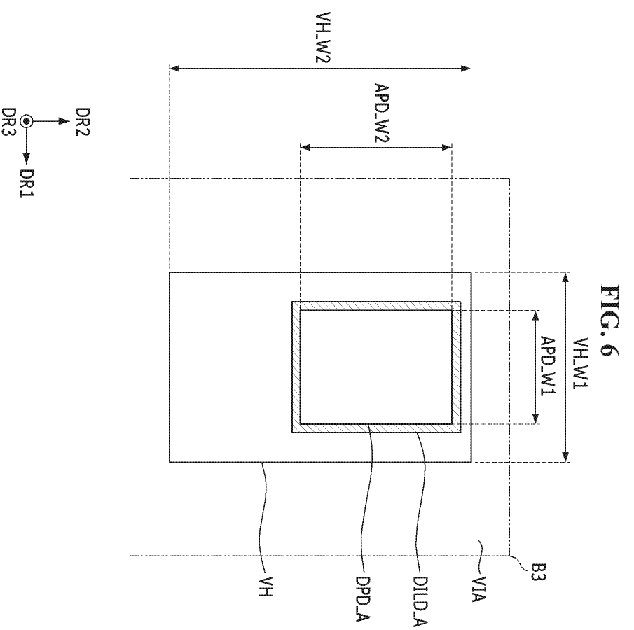

FIG. 6 is an enlarged view of portion B3 of the display device according to the embodiment of the present disclosure when the display panel and the driver circuit are bonded together.

Referring to FIG. 6, the width of the via hole VH in the first direction DR1 and the second direction DR2 may be larger than the width of the circuit fixing pad DPD_A of the driver circuit DDC such that the circuit fixing pad DPD_A of the driver circuit DDC may be inserted into the inside of the via hole VH.

When viewed from the top, the width VH_W1 of the via hole in the first direction DR1 may be greater than the width APD_W1 of the circuit fixing pad. For example, the width VH_W1 of the via hole in the first direction DR1 may be greater than the width APD_W1 of the circuit fixing pad by approximately 11 µm.

When viewed from the top, the width VH_W2 of the via hole in the second direction DR2 may be greater than the width APD_W2 of the circuit fixing pad. For example, the width VH_W2 of the via hole in the second direction DR2 may be greater than the width APD_W2 of the circuit fixing pad by approximately 30 µm.

It should be noted that the width of the via holes VH and the width of the circuit fixing pad DPD_A of the driver circuit DDC in the first direction DR1 and the second direction DR2 may vary and are not particularly limited as long as the circuit fixing pad DPD_A is inserted inside the via holes VH to work as an anchor to prevent slipping between the display panel DP and the driver circuit DDC.

In some aspects, when viewed from the top, the circuit fixing insulating layer DILD_A may be located inside the via hole VIA of the via layer VIA of the display panel DP together with the circuit fixing pad DPD_A. In some embodiments, the surface of the circuit fixing insulating layer DILD_A which crosses the surface facing the display panel DP may not be in direct contact with the inner surface of the via layer VIA defining the via hole VH. Alternatively, the surface of the circuit fixing insulating layer DILD_A which crosses the surface facing the display panel DP may be in direct contact with the inner surface of the via layer VIA defining the via hole VH.

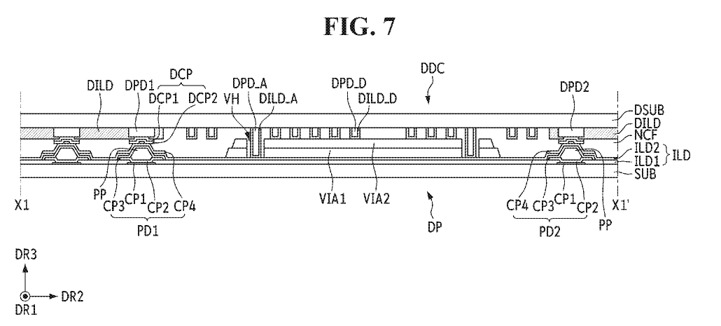

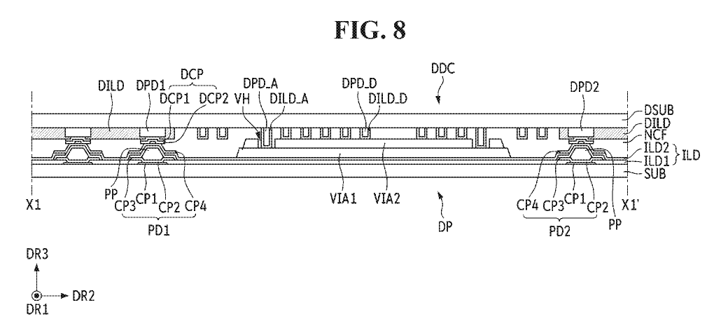

FIGS. 7 and 8 are cross-sectional views of a display device according to another embodiment of the present disclosure, taken along line X1 – X1' of FIG. 3.

The following descriptions will focus on differences, and the redundant descriptions will be omitted.

The example illustrated in FIG. 7 is different from the embodiment illustrated in FIG. 5 in that a via layer VIA may include a first via layer VIA1 located on a second interlayer dielectric layer ILD2 and a second via layer VIA2 located on the first via layer VIA1. A via hole VH may penetrate the first via layer VIA1 and the second via layer VIA2. In some embodiments, the surface of the circuit fixing insulating layer DILD_A which crosses the surface facing the display panel DP may not be in direct contact with the inner surfaces of the first via layer VIA1 and the second via layer defining the via hole VH. Alternatively, the surface of the circuit fixing insulating layer DILD_A which crosses the surface facing the display panel DP may be in direct contact with the inner surfaces of the first via layer VIA1 and the second via layer defining the via hole VH.

The example illustrated in FIG. 8 is different from the example illustrated in FIG. 7 in that a via hole VH does not penetrate the first via layer VIA1 but may penetrate the second via layer VIA2 (e.g., penetrate only the second via layer VIA2). In some embodiments, the surface of the circuit fixing insulating layer DILD_A which faces the display panel DP may be in direct contact with the first via layer VAI1. Alternatively, in some embodiments, the surface of the circuit fixing insulating layer DILD_A which faces the display panel DP may not be in direct contact with the first via layer VAI1.

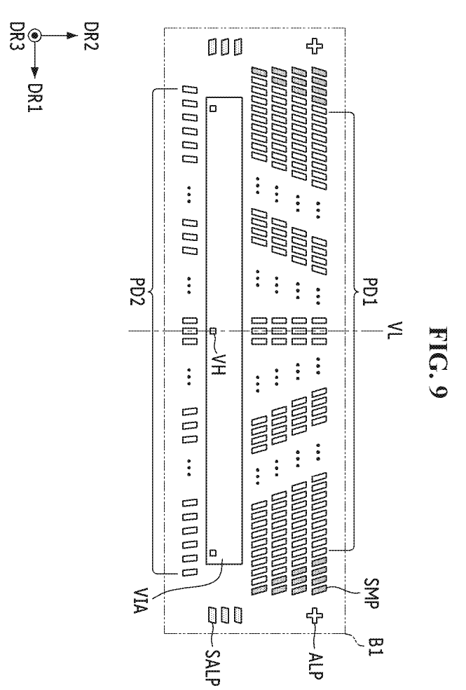

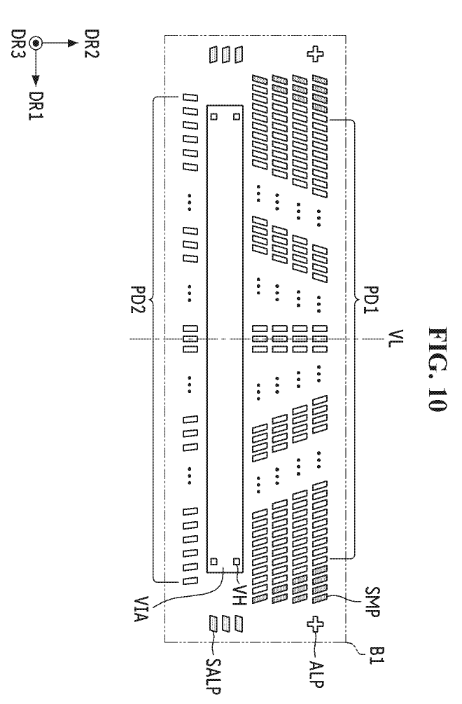

FIGS. 9 and 10 are enlarged views of portion B1 of FIG. 3 in a display device according to another embodiment.

The following descriptions will focus on differences, and the redundant descriptions will be omitted.

The example illustrated in FIG. 9 is different from the example illustrated in FIG. 3 in that a plurality of via holes VH may be arranged in a single row of via holes VH at the lower portion of the via layer VIA in the second direction DR2.

The example illustrated in FIG. 10 is different from the example illustrated in FIG. 3 in that a plurality of via holes VH may be arranged in two rows of via holes VH at the left and right corners of the via layer VIA, not on the reference line VL.

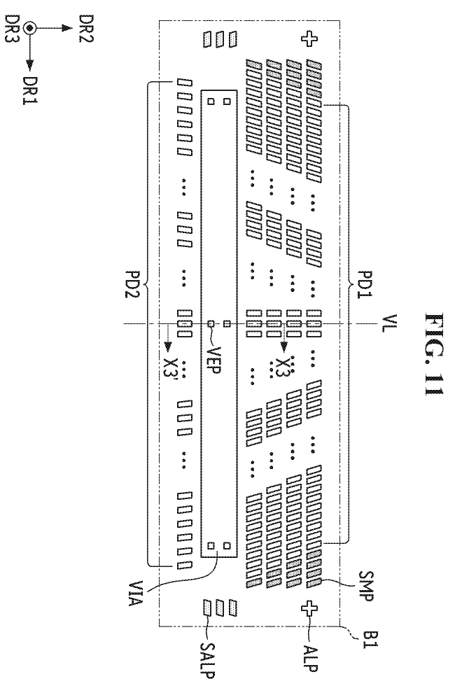

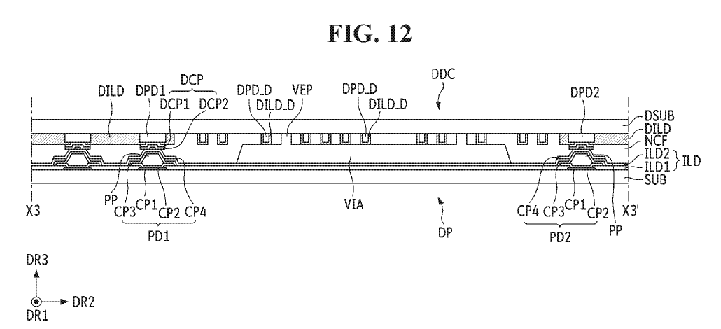

FIG. 11 is an enlarged view of portion B1 of FIG. 3 in a display device according to another embodiment. FIG. 12 is a cross-sectional view taken along line X3 – X3' of FIG. 11.

The following descriptions will focus on differences, and the redundant descriptions will be omitted.

Referring to FIGS. 11 and 12, a via layer VIA may include via protruding patterns VEP that protrude toward the driver circuit DDC. The via protruding patterns VEP may be located between the circuit dummy pads DPD_D of the driver circuit DDC. Each of the via protruding patterns VEP may be located between the circuit dummy pads DPD_D of the driver circuit DDC which are spaced apart from each other to anchor the driver circuit DDC and the display panel DP when bonding them so as to prevent slipping. In some embodiments, the surface of the via protruding patterns VEP which faces the driver circuit DDC may be in direct contact with the substrate DSUB of the driver circuit DDC. Alternatively, in some embodiments, the surface of the via protruding patterns VEP which faces the driver circuit DDC may not be in direct contact with the substrate DSUB of the driver circuit DDC. As the via protruding patterns VEP of the via layer VIA of the display panel DP are inserted between the circuit dummy pads DPD_D of the driver circuit DDC, the via protruding patterns VEP as inserted may prevent slipping that causes misalignment between the pads of the display panel DP and the pads of the driver circuit DDC when the display panel DP and the driver circuit DDC are bonded together. As a result, the reliability of the display device can be improved.

The display device according to the embodiment may be applied to a variety of electronic devices. An electronic device according to an embodiment includes the display device described herein, and may further include a module or device having additional features in addition to the display device.

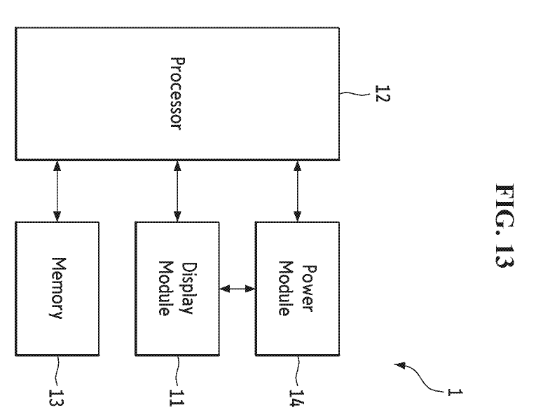

FIG. 13 is a block diagram of an electronic device according to an embodiment of the present disclosure.

Referring to FIG. 13, an electronic device 1 according to an embodiment of the present disclosure may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 15 may store data information supportive of the operation of the processor 12 or the display module 11. In an example in which the processor 12 executes an application stored in the memory 15, an image data signal and/or an input control signal may be transmitted to the display module 11. The display module 11 may process the received signal and output image information through a display screen.

The power module 14 may include a power supply module such as, for example, a power adapter and a battery device, and a power conversion module that converts the power supplied by the power supply module to generate power for the operation of the electronic device 1.

At least one of the elements of the electronic device 1 described herein may be included in the display devices according to the embodiments described herein. In some aspects, some of the individual modules functioning as a single module may be included in the display device while some others may be provided separately from the display device. For example, the display device may include the display module 11, and the processor 12, the memory 13 and the power module 14 may be implemented as other devices inside the electronic device 1 instead of the display device.

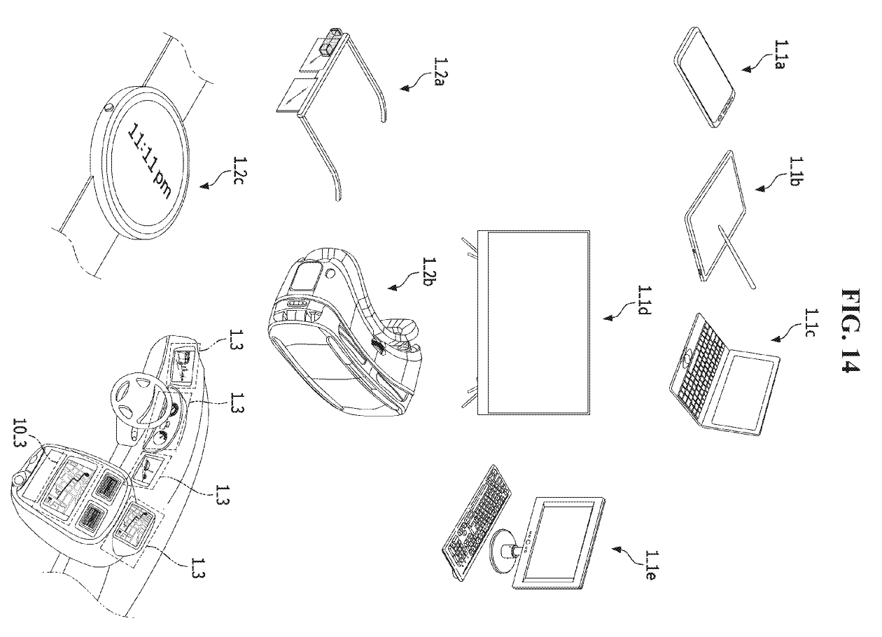

FIG. 14 is a view illustrating electronic devices according to a variety of embodiments of the present disclosure.

Referring to FIG. 14, a variety of electronic devices employing display devices according to embodiments may include not only image display electronic devices such as a smart phone 1_1a, a tablet PC 1_1b, a laptop computer 1_1c, a TV 1_1d and a desktop monitor 1_1e, but also wearable electronic devices including display modules such as smart glasses 1_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

In concluding the detailed description, those skilled in the art will appreciate that many variations and modifications can be made to the example embodiments without substantially departing from the principles of the present invention. Therefore, the disclosed example embodiments of the present disclosure are used in a generic and descriptive sense and not for purposes of limitation.

What is claimed is:

1. A display device comprising:
a first substrate;
a display panel comprising a first signal pad located on the first substrate, a via layer located on an outer side of the first signal pad, and a second signal pad located on an outer side of the via layer; and
a driver circuit located on the display panel and connected to the first signal pad and the second signal pad of the display panel,
wherein:
the driver circuit comprises:
a second substrate;
a first circuit signal pad located on the second substrate;
a circuit fixing pad located on an outer side of the first circuit signal pad; and
a second circuit signal pad located on an outer side of the circuit fixing pad,
the via layer of the display panel comprises a via hole penetrating the via layer,
the first circuit signal pad and the second circuit signal pad of the driver circuit are connected with the first signal pad and the second signal pad of the display panel, respectively, and
the circuit fixing pad overlaps with the via hole of the display panel and is further located inside the via hole.

2. The display device of claim 1, wherein:
the display panel further comprises an insulating layer located between the first substrate and the via layer,
the driver circuit further comprises a circuit fixing insulating layer covering the circuit fixing pad, and
a surface of the circuit fixing insulating layer facing the display panel is in direct contact with the insulating layer of the display panel.

3. The display device of claim 2, wherein a surface of the circuit fixing insulating layer that crosses the surface facing the display panel is not in direct contact with an inner surface of the via layer defining the via hole.

4. The display device of claim 2, wherein a surface of the circuit fixing insulating layer that crosses the surface facing the display panel is in direct contact with an inner surface of the via layer defining the via hole.

5. The display device of claim 1, wherein:
the display panel further comprises an insulating layer located between the first substrate and the via layer,
the driver circuit further comprises a circuit fixing insulating layer covering the circuit fixing pad, and
a surface of the circuit fixing insulating layer facing the display panel is not in direct contact with the insulating layer of the display panel.

6. The display device of claim 5, wherein a surface of the circuit fixing insulating layer that crosses the surface facing the display panel is not in direct contact with an inner surface of the via layer defining the via hole.

7. The display device of claim 5, wherein a surface of the circuit fixing insulating layer that crosses the surface facing the display panel is in direct contact with an inner surface of the via layer defining the via hole.

8. The display device of claim 1, wherein:
the driver circuit further comprises a circuit dummy pad located between the first circuit signal pad and the second circuit signal pad and located around the circuit fixing pad, and
a thickness of the circuit dummy pad and a thickness of the circuit fixing pad are different from each other.

9. The display device of claim 8, wherein the thickness of the circuit fixing pad is greater than the thickness of the circuit dummy pad.

10. The display device of claim 8, wherein:
the driver circuit further comprises a circuit dummy insulating layer covering the circuit dummy pad, and
a surface of the circuit dummy insulating layer facing the display panel is in direct contact with the via layer.

11. The display device of claim 8, wherein:
the driver circuit further comprises a circuit dummy insulating layer covering the circuit dummy pad, and
a surface of the circuit dummy insulating layer facing the display panel is not in direct contact with the via layer.

12. The display device of claim 1, wherein:
the via layer comprises a first via layer located on the first substrate and a second via layer located on the first via layer, and
the via hole penetrates the second via layer but not the first via layer.

13. The display device of claim 12, wherein:
the driver circuit further comprises a circuit fixing insulating layer covering the circuit fixing pad, and
a surface of the circuit fixing insulating layer facing the display panel is in direct contact with the first via layer.

14. The display device of claim 12, wherein:
the driver circuit further comprises a circuit fixing insulating layer covering the circuit fixing pad, and
a surface of the circuit fixing insulating layer facing the display panel is not in direct contact with the first via layer.

15. A display device comprising:
a first substrate;
a display panel comprising a first signal pad located on the first substrate, a via layer located on an outer side of the first signal pad, and a second signal pad located on an outer side of the via layer; and
a driver circuit located on the display panel and connected to the first signal pad and the second signal pad of the display panel,
wherein:
the driver circuit comprises:
a second substrate;
a first circuit signal pad located on the second substrate;
a plurality of circuit dummy pads located on an outer side of the first circuit signal pad and spaced apart from one another; and
a second circuit signal pad located on an outer side of the plurality of circuit dummy pads,
the first circuit signal pad and the second circuit signal pad of the driver circuit are connected to the first signal pad and the second signal pad of the display panel, respectively,
the via layer of the display panel further comprises a via protruding pattern protruding toward the driver circuit, and
the via protruding pattern is located between the plurality of circuit dummy pads of the driver circuit.

16. The display device of claim 15, wherein a surface of the via protruding pattern facing the driver circuit is in direct contact with the second substrate of the driver circuit.

17. The display device of claim 16, wherein a surface of the via protruding pattern facing the driver circuit is not in direct contact with the second substrate of the driver circuit.

18. The display device of claim 16, wherein:
the driver circuit further comprises a circuit dummy insulating layer covering the plurality of circuit dummy pads, and
a surface of the circuit dummy insulating layer facing the display panel is in direct contact with the via layer.

19. The display device of claim 16, wherein:
the driver circuit further comprises a circuit dummy insulating layer covering the plurality of circuit dummy pads, and
a surface of the circuit dummy insulating layer facing the display panel is not in direct contact with the via layer.

20. An electronic device comprising:
a display device for displaying an image; and
a processor for transmitting an image data signal for displaying the image to the display device,
wherein the display device comprises:
a first substrate;
a display panel comprising a first signal pad located on the first substrate, a via layer located on an outer side of the first signal pad, and a second signal pad located on an outer side of the via layer; and
a driver circuit located on the display panel and connected to the first signal pad and the second signal pad of the display panel,
wherein:
the driver circuit comprises:
a second substrate;
a first circuit signal pad located on the second substrate;
a circuit fixing pad located on an outer side of the first circuit signal pad; and
a second circuit signal pad located on an outer side of the circuit fixing pad,
the via layer of the display panel comprises a via hole penetrating the via layer,
the first circuit signal pad and the second circuit signal pad of the driver circuit are connected with the first signal pad and the second signal pad of the display panel, respectively, and
the circuit fixing pad overlaps with the via hole of the display panel and is further located inside the via hole.
